(19) United States
(12) Patent Application Publication
(10) Pub. No.: US 2023/0134840 A1
(43) Pub. Date: May 4, 2023

(54) COMPRESSION OF POWER DELAY PROFILE

(71) Applicant: Samsung Electronics Co., Ltd., Suwon-si (KR)

(72) Inventors: Ramin SOLTANI, Carlsbad, CA (US); Hyukjoon KWON, San Diego, CA (US); Federico PENNA, San Diego, CA (US); Jungmin PARK, Hwaseong-si (KR)

(21) Appl. No.: 17/842,694

(22) Filed: Jun. 16, 2022

Related U.S. Application Data
(60) Provisional application No. 63/273,007, filed on Oct. 28, 2021.

(51) Int. Cl. H04B 17/364; H04L 5/00; H04W 72/04

(52) U.S. Cl. CPC H04B 17/364; H04L 5/0048; H04W 72/0446; H04W 72/0453; H04W 72/0473

(57) ABSTRACT

A system and method for storing a power delay profile in compressed form. In some embodiments, the method includes: identifying, in a power delay profile including a first group of taps, a first arrival tap corresponding to a first arrival path; identifying a first subset of taps, the first subset being a subset of the first group and including the first arrival tap; identifying a second subset of taps, the second subset being a subset of the first group and being disjoint from the first subset; and storing, in a memory, the union of the first subset and a proper subset of the second subset.

### CROSS-REFERENCE TO RELATED APPLICATION(S)

The present application claims priority to and the benefit of U.S. Provisional Application No. 63/273,007, filed Oct. 28, 2021, entitled “COMPRESSION OF POWER DELAY PROFILE BUFFER”, the entire content of which is incorporated herein by reference.

### FIELD

One or more aspects of embodiments according to the present disclosure relate to wireless communications, and more particularly to a system and method for storing a power delay profile in compressed form.

### BACKGROUND

In a wireless communication system, a receiver may generate, from a reference signal transmitted by a transmitter, a power delay profile (PDP). The receiver may generate a plurality of such PDPs, e.g., one for each of a plurality of reference signals transmitted by the transmitter. The storing of the PDPs in the receiver may consume significant resources, e.g., a significant amount of memory.

It is with respect to this general technical environment that aspects of the present disclosure are related.

### SUMMARY

According to an embodiment of the present disclosure, there is provided a method, including: identifying, in a power delay profile including a first group of taps, a first arrival tap corresponding to a first arrival path; identifying a first subset of taps, the first subset being a subset of the first group and including the first arrival tap; identifying a second subset of taps, the second subset being a subset of the first group and being disjoint from the first subset; and storing, in a memory, the union of the first subset and a proper subset of the second subset.

In some embodiments, the first group of taps includes all of the taps of the power delay profile.

In some embodiments, the power delay profile further includes a second group of taps, the second group and the first group being disjoint.

In some embodiments, the method further includes: identifying a principal tap within the second group; identifying a third subset of taps, the third subset being a subset of the second group, and including the principal tap; identifying a fourth subset of taps, the fourth subset being a subset of the second group and being disjoint from the third subset; and storing, in the memory, the union of the third subset and a proper subset of the fourth subset.

In some embodiments, the first subset includes a first contiguous plurality of taps including a tap immediately adjacent to and delayed with respect to the first arrival tap and a second contiguous plurality of taps including a tap immediately adjacent to and advanced with respect to the first arrival tap.

In some embodiments, the first contiguous plurality of taps includes more taps than the second contiguous plurality of taps.

In some embodiments, the method further includes identifying the proper subset of the second subset, the identifying including excluding a regularly spaced subset from the second subset.

In some embodiments, the method further includes reconstituting, from taps stored in the memory, a decompresssed power delay profile.

In some embodiments, the reconstituting of the decompresssed power delay profile includes using linear interpolation.

In some embodiments, the reconstituting of the decompresssed power delay profile includes using simple extension.

According to an embodiment of the present disclosure, there is provided a User Equipment, including: a processing circuit; and memory connected to the processing circuit, the memory storing instructions that, when executed by the processing circuit, cause the User Equipment to perform a method, the method including: identifying, in a power delay profile including a first group of taps, a first arrival tap corresponding to a first arrival path; identifying a first subset of taps, the first subset being a subset of the first group, and including the first arrival tap; identifying a second subset of taps, the second subset being a subset of the first group and being disjoint from the first subset; and storing, in a memory, the union of the first subset and a proper subset of the second subset.

In some embodiments, the first group of taps includes all of the taps of the power delay profile.

In some embodiments, the power delay profile further includes a second group of taps, the second group and the first group being disjoint.

In some embodiments, the method further includes: identifying a principal tap within the second group; identifying a third subset of taps, the third subset being a subset of the second group, and including the principal tap; identifying a fourth subset of taps, the fourth subset being a subset of the second group and being disjoint from the third subset; and storing, in the memory, the union of the third subset and a proper subset of the fourth subset.

In some embodiments, the first subset includes a first contiguous plurality of taps including a tap immediately adjacent to and delayed with respect to the first arrival tap and a second contiguous plurality of taps including a tap immediately adjacent to and advanced with respect to the first arrival tap.

In some embodiments, the first contiguous plurality of taps includes more taps than the second contiguous plurality of taps.

In some embodiments, the method further includes identifying the proper subset of the second subset, the identifying including excluding a regularly spaced subset from the second subset.

In some embodiments, the method further includes reconstituting, from taps stored in the memory, a decompresssed power delay profile.

In some embodiments, the reconstituting of the decompresssed power delay profile includes using linear interpolation.

According to an embodiment of the present disclosure, there is provided a User Equipment, including: means for processing; and memory connected to the means for processing, the memory storing instructions that, when executed by the means for processing, cause the User Equipment to perform a method, the method including: identifying, in a power delay profile including a first group of taps, a first arrival tap corresponding to a first arrival path; identifying a first subset of taps, the first subset being a subset of the first group, and including the first arrival tap; identifying a second subset of taps, the second subset being a subset of the first group and being disjoint from the first subset; and storing, in a memory, the union of the first subset and a proper subset of the second subset.

### BRIEF DESCRIPTION OF THE DRAWINGS

These and other features and advantages of the present disclosure will be appreciated and understood with reference to the specification, claims, and appended drawings wherein:

FIG. 1 is a schematic graph of a power delay profile, according to an embodiment of the present disclosure;

FIG. 2A is a slot diagram, according to an embodiment of the present disclosure;

FIG. 2B is a resource element diagram, according to an embodiment of the present disclosure;

FIG. 3A is an illustration of a method for reconstituting a decompresssed power delay profile, according to an embodiment of the present disclosure;

FIG. 3B is an illustration of a method for reconstituting a decompresssed power delay profile, according to an embodiment of the present disclosure;

FIG. 4 is a flowchart, according to an embodiment of the present disclosure;

FIG. 5 is a schematic graph of a power delay profile, according to an embodiment of the present disclosure;

FIG. 6A is a table of simulation parameters, according to an embodiment of the present disclosure;

FIG. 6B is a table of simulation results, according to an embodiment of the present disclosure;

FIG. 6C is a table of simulation results, according to an embodiment of the present disclosure;

FIG. 7 is a flowchart, according to an embodiment of the present disclosure; and

FIG. 8 is a block diagram of a system for wireless communications, according to an embodiment of the present disclosure.

### DETAILED DESCRIPTION

The detailed description set forth below in connection with the appended drawings is intended as a description of exemplary embodiments of a system and method for storing a power delay profile in compressed form provided in accordance with the present disclosure and is not intended to represent the only forms in which the present disclosure may be constructed or utilized. The description sets forth the features of the present disclosure in connection with the illustrated embodiments. It is to be understood, however, that the same or equivalent functions and structures may be accomplished by different embodiments that are also intended to be encompassed within the scope of the disclosure. As denoted elsewhere herein, like element numbers are intended to indicate like elements or features.

In a wireless modem, a power delay profile (PDP) shows the intensity of a signal as a function of time delay for a multipath channel. The PDP represents the average effect of obstacles affecting the transmission of radio signals. The PDP may be employed for applications such as channel estimation and time synchronization, which may be used for detection and decoding of the received signals.

The power delay profile is defined as

f(τ)=E[|h(t,τ)|²],

where |h(t, τ)|² is the instantaneous PDP, E[⋅] denotes expected value over time, and h(t, τ) is the impulse response of the wireless channel.

A buffer (e.g., a region in a memory of the modem or receiver) may be used to store the PDP and provide it to different parts of the modem. A PDP may be calculated for each of a plurality of different reference signals such as the secondary synchronization signal (SSS) or the tracking reference signal (TRS). Each PDP may be stored in a buffer available to other parts of modem. The PDPs may consume a significant amount of storage space in the buffer.

As such, in some embodiments, compression is used to reduce the space occupied in the buffer by the PDPs. The compression may involve dividing the PDP elements into three sets: (A) elements very close to the first arrival path (FAP), (B) elements close to the FAP, and (C) elements far from FAP. Closeness of an element to the FAP may be based on the difference between the index of the element and the FAP, in a circular sense, as discussed in further detail below, and each of the sets (A), (B), and (C) may be asymmetric with respect to the FAP, e.g., the number elements after the FAP may be larger than the number of elements before FAP.

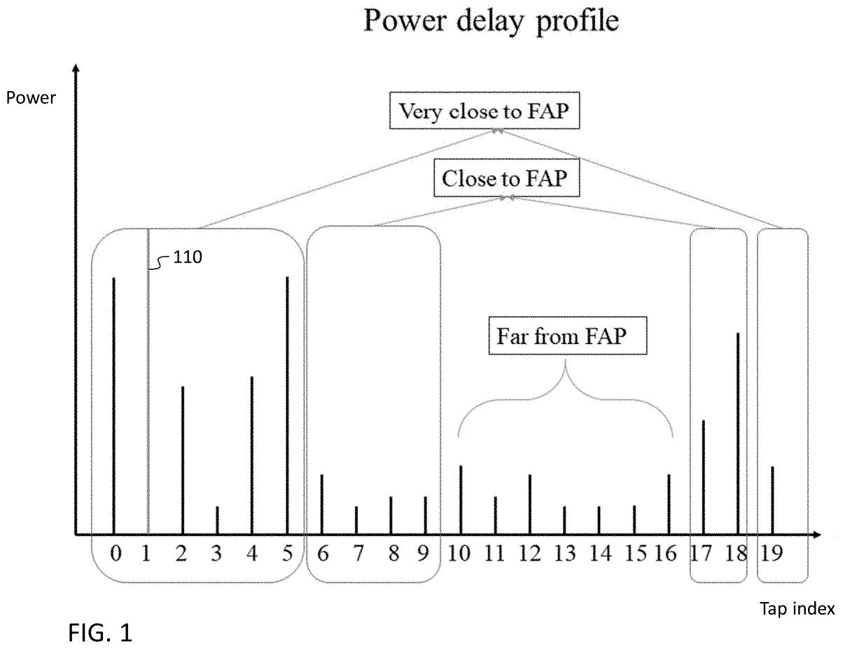

FIG. 1 shows an example of a PDP, which is illustrated as a graph of the power in each tap, for a plurality of taps (20 taps, numbered 0 through 19, in the example of FIG. 1). In the example of FIG. 1, the first arrival tap (i.e., the tap corresponding to the FAP 110) is tap 1, A={0, 1, 2, 3, 4, 5, 19}, B={6, 7, 8, 9, 17, 18}, and C={10, 11, 12, 13, 14, 15, 16}. In some embodiments, the compression involves storing all elements of A, storing a proper subset of B, and storing none of the elements of C. The effect of this compression algorithm may be that a full copy of the first few arrival paths is captured, a lower resolution copy of the next arrival paths is captured, and the remaining arrival paths (some or all of which may appear in the estimate of the PDP primarily as a result of noise) are disregarded.

In some embodiments, the compression algorithm includes a step of asymmetric tap reduction. This step may involve removing the taps that are far from the FAP 110. For a PDP vector denoted X=(X₀, X₁, . . . , X_{N-1}), and the index of the FAP 110 in X denoted by F, the i-th tap may be removed if

$$Mod ( i - F , N ) > round ( \frac{UQ}{100} ) and Mod ( i - F , N ) < N - U + round ( \frac{UQ}{100} ) .$$

where U is the number of remaining taps after this step of the algorithm and Q (%) is the percentage of the remaining taps that appear after the FAP 110. For instance, if the FAP 110 is tap 1, U=12, Q=70%, and the total number of PDP elements before compression is N=20, then this step of PDP compression involves removing taps 10, 11, 12, 13, 14, 15, and 16. The distance between two taps, as used herein, is defined in a circular manner, e.g., the distance between tap 18 and tap 0 is 2. Similarly, a set of taps is considered contiguous if the distance between each pair of adjacent elements in the set is one; for example, the set consisting of taps 17, 18, 19, and 0 is contiguous.

Storage of the 8 taps after the FAP 110 ensures capturing the first few taps and the storage of the 4 taps before the FAP 110 (taps 17, 18, 19, and 0) accounts for possible errors in FAP estimation. The absence of a constraint requiring that the same number of taps on the right and left side of the FAP 110 be kept may reduce the likelihood that redundant taps on the left side of the FAP 110 are needlessly kept, reducing the compression gain.

In some embodiments, the compression algorithm further includes a step of region based downsampling. This step of the compression algorithm may involve keeping PDP elements very close to the FAP 110 (set A) and downsampling PDP elements close to the FAP 110 (set B) with rate p (e.g., excluding a regularly spaced subset of these elements) so that only a proper subset, denoted B′, of the set B is kept. For example, from all of the remaining taps from asymmetric tap reduction (from the sets A and B), P (%) of the elements may be in the set A, where

$$P = \frac{\vert A \vert}{\vert A \vert + \vert B \vert} \times 100 \% ,$$

and where |⋅| denotes the cardinality of a set.

In some embodiments, the i-th tap is removed if all of the following requirements are satisfied:

$$Mod ( i - F , ρ ) > 0 \qquad ( 1 )$$

$$Mod ( i - F , N ) > round ( \frac{UPQ}{10000} ) \qquad ( 2 )$$

$$Mod ( i - F , N ) < N - ⌊ \frac{UP}{100} ⌋ + round ( \frac{UPQ}{10000} ) \qquad ( 3 )$$

Equation (1) above applies the downsampling index selection and the combination of Equations (2) and (3) ensures that that index i is outside of the area in which downsampling is not performed (i.e., outside of the set A).

This step may be illustrated using the example from above, with a downsampling rate of ρ=2, with P=50%, and with an FAP 110 at tap 1 (i=1). Then, on the right side of the FAP 110, the taps remaining after the step of asymmetric tap reduction are i=2,3,4,5, 6, 7, 8, 9. The first 50% (i=2, 3, 4, 5) are all kept (because P=50%). Then the taps (i=6, 7, 8, 9) are downsampled with rate ρ=2 to obtain (i=7, 9). As such, the remaining taps on the right side of the FAP 110 are i=2,3,4,5, 7, 9.

On the left side of the FAP 110, the taps remaining after the step of asymmetric tap reduction are i=0, 19, 18, 17. The first 50% (i=0, 19) are kept (because P=50%). Then, the taps (i=18, 17) are downsampled with rate ρ=2 to obtain (i=17). As such, the remaining taps on the left side of the FAP 110 are i=0, 19, 17.

Finally, the number of elements in the compressed version of the PDP is

$${N}^{′} = 1 + {R}_{2} + ⌈ \frac{{R}_{1} - {R}_{2} - mod ( {R}_{2} + 1 , ρ )}{ρ} ⌉ + {L}_{2} + ⌈ \frac{{L}_{1} - {L}_{2} - mod ( N - {L}_{1} , ρ )}{ρ} ⌉ ,$$

$$where$$

$${R}_{1} = round ( \frac{QU}{100} ) ,$$

$${L}_{1} = U - {R}_{1} ,$$

$${R}_{2} = round ( \frac{UPQ}{10000} ) , and$$

$${L}_{2} = ⌊ \frac{UP}{100} ⌋ - {R}_{2} .$$

In the above described method, after a tap that corresponds to the FAP 110 is identified, taps in two disjoint subsets of the set of PDP taps (the subsets A and B) may be identified; all of the first subset (A) may be stored in memory (e.g., in the buffer), and a proper subset (e.g., a downsampled subset) of the second subset (B) may also be stored in memory. A third subset (C) may be discarded (i.e., not stored in the memory); as such, the union of the first subset (A) and the downsampled version of the second subset (B) may be a proper subset of (i.e., may include less than all of) the set of PDP taps. The first subset (A) may include (i) the tap that corresponds to the FAP 110, (ii) a first contiguous plurality of taps including a tap immediately adjacent to and delayed with respect to the first arrival tap (e.g., the taps with i=2, 3, 4, 5 in the example above) and (iii) a second contiguous plurality of taps including a tap immediately adjacent to and advanced with respect to the first arrival tap (e.g., the taps with i=0, 19 in the example above). The first contiguous plurality of taps (those on the right of the FAP 110) may include more taps than the second contiguous plurality of taps (those on the left of the FAP 110).

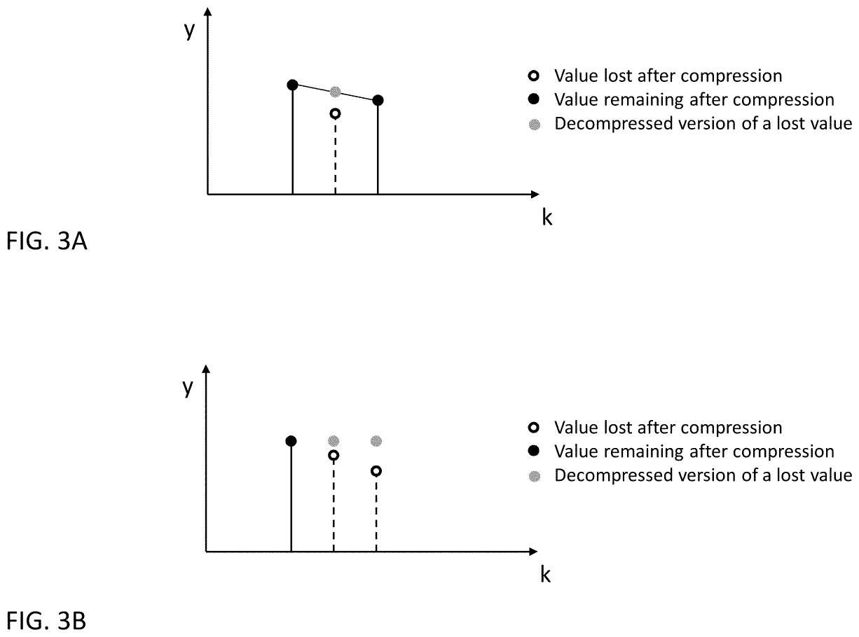

Various methods may be used to reconstitute the decompresssed PDP, e.g., to recover the elements removed in the downsampling step. One such method, illustrated in FIG. 3A, involves linear interpolation. For every removed tap value Xₖ, (K−1, X_{K-1}) and (K+1, X_{K+1}) may be used to calculate a and b for f(K)=a+bK. Then, the recovered version of Xₖ may be X′ₖ=a+bK.

Another method for recovering the elements removed in the downsampling step is simple extension, illustrated in FIG. 3B. For every removed tap value Xₖ, the value of the previous tap X_{K-1} or the value of the next tap X_{K∓1}, may be used. If the previous tap is also removed (downsampling rate is larger than 2), then the algorithm may go back until it finds a tap that is not removed due to downsampling and uses that value (similarly, if the next tap is also removed, the algorithm may advance forward until it finds a tap that has not been removed). For instance, if with downsampling rate 4 the tap value X_{4K} is kept but X_{4K+1}, X_{4K+2}, X_{4K+3}, are removed, then with decompression, X′_{4K+1}=X′_{4K+2}=X′_{4K+3}=X_{4K}. An analogous approach may be used for interpolation if the downsampling rate is greater than 2.

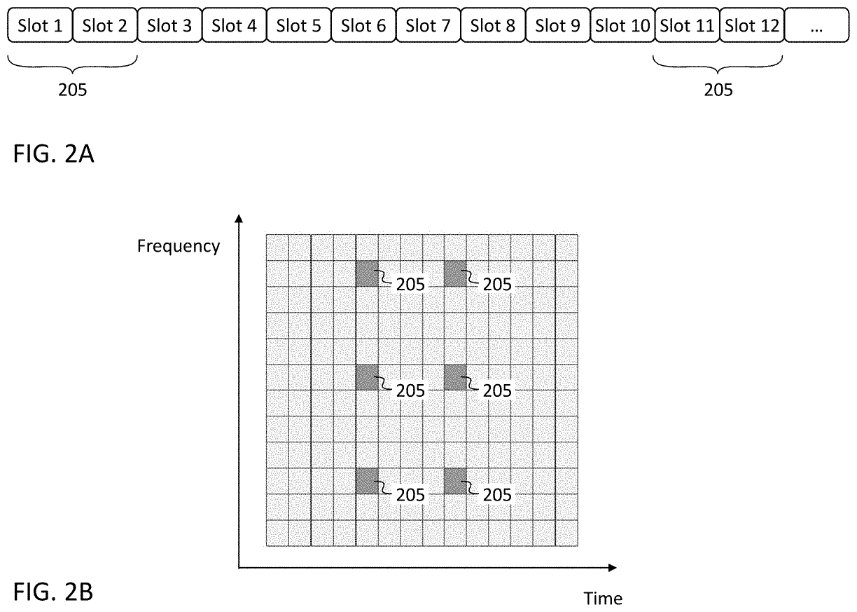

The compression methods described herein may be universally applicable to reference signals. For example, the methods may be used for the PDP of a TRS, i.e., channel state information reference signal (CSI-RS) for tracking. The algorithm may also apply to the PDP obtained from other reference signals. The TRS appears periodically in the time domain in one slot or two consecutive slots, with two symbols per slot. FIG. 2A shows an example in which the TRS 205 appears in two slots per period, with periodicity of 10 slots. In the frequency domain, the TRS is inserted in three resource elements (REs) in every resource block (RB). FIG. 2B shows an example of the TRS allocation in a block which has an RB in the frequency domain and one slot in the time domain.

The inverse fast Fourier transform (IFFT) of any such reference symbol may be taken to obtain the noisy observation of the instantaneous impulse response of the wireless channel \tilde{h}(t, τ):

\tilde{h}(t,τ)=h(t,τ)+n(t),

where n(t) is the noise of observation of h(t, τ) from the reference signal (e.g., from the TRS). Then, the time samples of |\tilde{h}(t, τ)|²−σ² may be stored in the buffer, where σ² is the noise power. The average of the |\tilde{h}(t, τ)|²−σ² over time is the PDP. The size of the PDP buffer depends on the cellular network configuration, e.g., on the number of RBs allocated for the reference signal and the density of the reference signal. For instance, for the case of a TRS allocated in 106 RBs, the buffer size may be N=512.

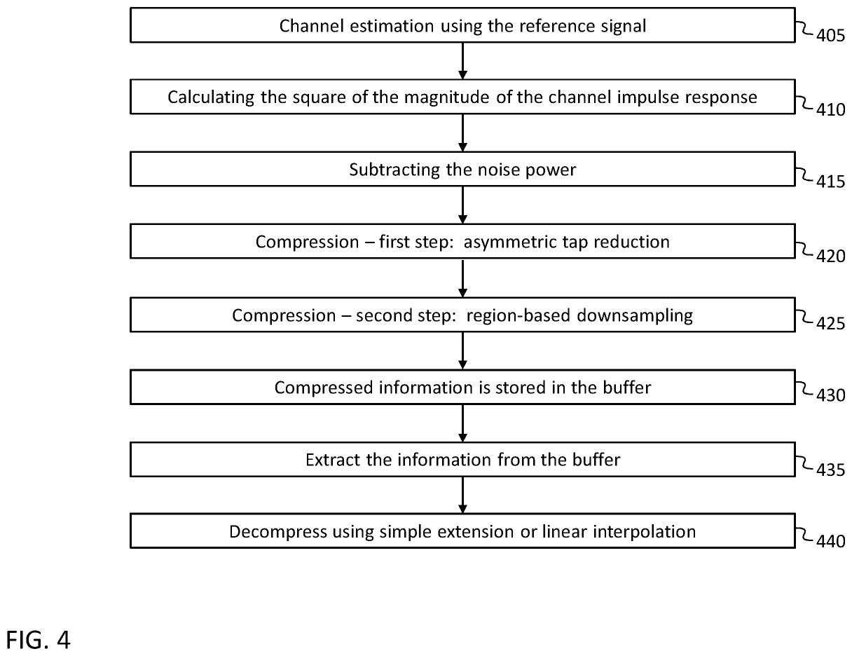

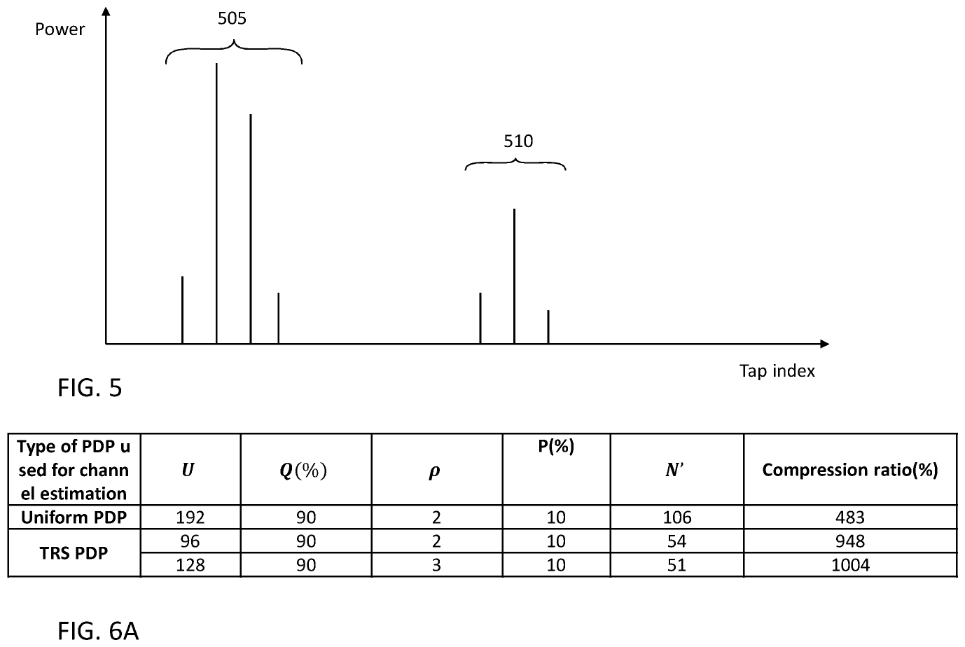

The flowchart of FIG. 4 illustrates the operating procedures. The method may include performing, at 405, channel estimation using the reference signal; calculating, at 410, the square of the magnitude of the channel impulse response; subtracting, at 415, the noise power; performing, at 420, a first step of compression, asymmetric tap reduction; performing, at 425, a second step of compression, region-based downsampling; storing, at 430, the compressed information in the buffer; extracting, at 435, the information from the buffer; and decompressing, at 440, the compressed information (e.g., reconstituting the decompresssed PDP) using extension (or “simple extension”) or linear interpolation. In some embodiments a method according to an embodiment disclosed herein may be practiced one group at a time for multiple groups 505, 510 of taps, as illustrated in FIG. 5 for an embodiment with two groups (in some embodiments the method is practiced for more than two groups, in an analogous manner). Within each group, a first subset and a second subset may be identified, and all of the first subset and a proper subset of the second subset may be stored in memory. Each group may include a principal tap (which, in one of the groups may be the first arrival tap, and which in other groups may be, e.g., the tap having the highest power), and the algorithm may be applied treating the principal tap in each group in which it is not the first arrival tap as though it were the first arrival tap.

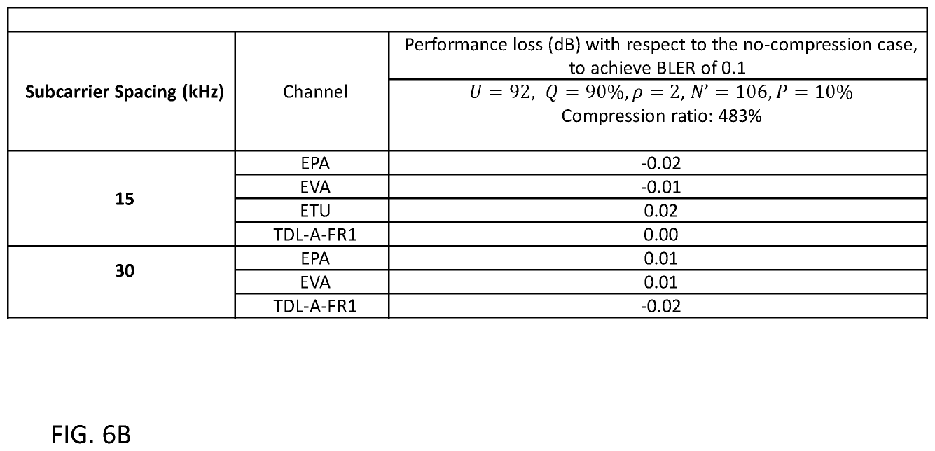

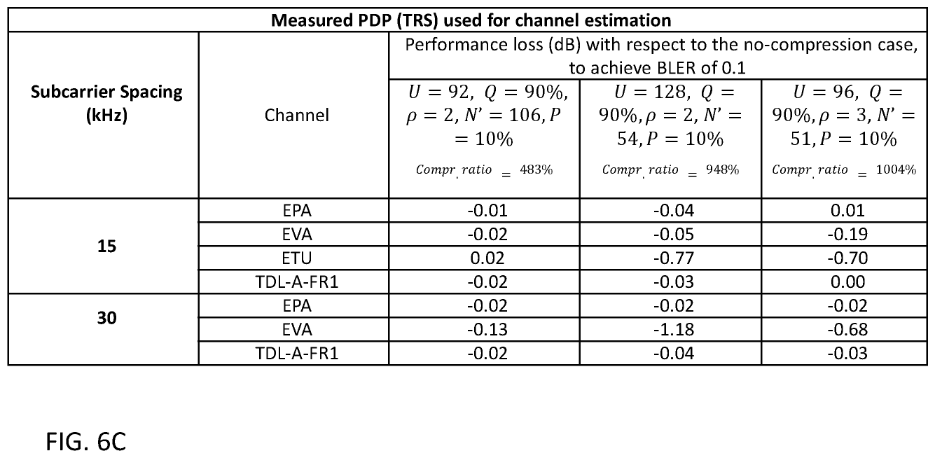

Simulations were performed to assess the performance of an example of a compression method, according to one embodiment. FIG. 6A shows simulation parameters, where the compression ratio is the ratio

$$\frac{Uncompressed size}{Compressed size} .$$

Simulation results are shown for decompression being done either by linear interpolation or simple extension; channel estimation being done by either a uniform PDP or a measured PDP (the actual PDP measured from the reference signal), several channels (extended pedestrian A (EPA) with Doppler frequency of 5 Hz, extended vehicular A (EVA) with Doppler frequency of 30 Hz, extended typical urban (ETU) with Doppler frequency of 70 Hz, and tapped delay line A frequency range 1 (TDL-A-FR1) with Doppler frequency of 5 Hz) and with time offsets of 1, 2, and 3 PPM. The simulation results are shown in FIGS. 6B and 6C.

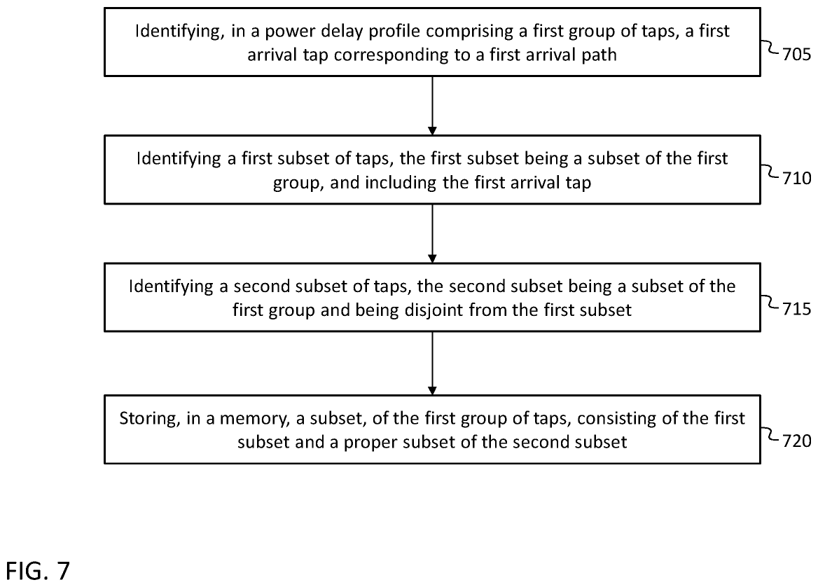

FIG. 7 shows a flowchart of a method. In some embodiments, the method includes identifying, AT 705, in a power delay profile comprising a first group of taps, a first arrival tap corresponding to a first arrival path; identifying, at 710, a first subset of taps, the first subset being a subset of the first group, and including the first arrival tap; identifying, at 715, a second subset of taps, the second subset being a subset of the first group and being disjoint from the first subset; and storing, at 720, in a memory, the union of (i) the first subset and (ii) a proper subset of the second subset.

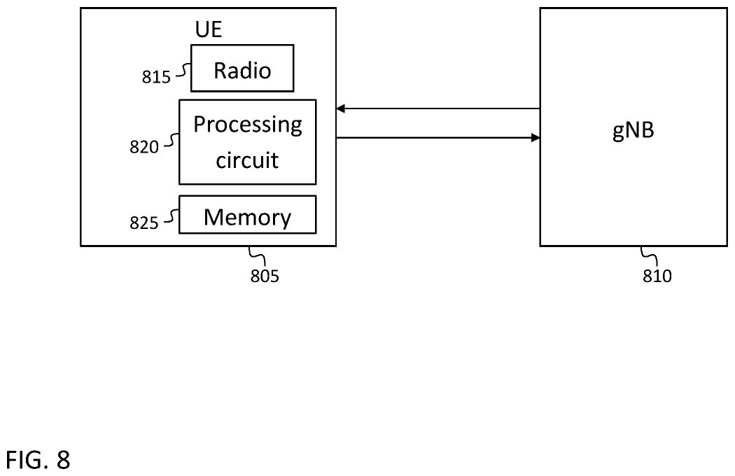

FIG. 8 shows a system including a UE 805 and a gNB 810, in communication with each other. The UE may include a radio 815 and a processing circuit (or a means for processing) 820, which may include or be connected to a memory 825, and which may perform various methods disclosed herein, e.g., the method illustrated in FIG. 4. For example, the processing circuit 820 may receive, via the radio 815, transmissions from the network node (gNB) 810, and the processing circuit 820 may transmit, via the radio 815, signals to the gNB 810.

Certain examples are described herein in the context of a mobile (e.g., 5G) communications system, but the methods disclosed herein are not limited to use in such a system and may be used in any communication system in which power delay profiles are generated and stored (e.g., in a WiFi system).

As used herein, “a portion of” something means “at least some of” the thing, and as such may mean less than all of, or all of, the thing. As such, “a portion of” a thing includes the entire thing as a special case, i.e., the entire thing is an example of a portion of the thing. As used herein, when a second quantity is “within Y” of a first quantity X, it means that the second quantity is at least X-Y and the second quantity is at most X+Y. As used herein, when a second number is “within Y %” of a first number, it means that the second number is at least (1−Y/100) times the first number and the second number is at most (1+Y/100) times the first number. As used herein, the term “or” should be interpreted as “and/or”, such that, for example, “A or B” means any one of “A” or “B” or “A and B”.

Each of the terms “processing circuit” and “means for processing” is used herein to mean any combination of hardware, firmware, and software, employed to process data or digital signals. Processing circuit hardware may include, for example, application specific integrated circuits (ASICs), general purpose or special purpose central processing units (CPUs), digital signal processors (DSPs), graphics processing units (GPUs), and programmable logic devices such as field programmable gate arrays (FPGAs). In a processing circuit, as used herein, each function is performed either by hardware configured, i.e., hard-wired, to perform that function, or by more general-purpose hardware, such as a CPU, configured to execute instructions stored in a non-transitory storage medium. A processing circuit may be fabricated on a single printed circuit board (PCB) or distributed over several interconnected PCBs. A processing circuit may contain other processing circuits; for example, a processing circuit may include two processing circuits, an FPGA and a CPU, interconnected on a PCB.

As used herein, the term “array” refers to an ordered set of numbers regardless of how stored (e.g., whether stored in consecutive memory locations, or in a linked list).

As used herein, when a method (e.g., an adjustment) or a first quantity (e.g., a first variable) is referred to as being “based on” a second quantity (e.g., a second variable) it means that the second quantity is an input to the method or influences the first quantity, e.g., the second quantity may be an input (e.g., the only input, or one of several inputs) to a function that calculates the first quantity, or the first quantity may be equal to the second quantity, or the first quantity may be the same as (e.g., stored at the same location or locations in memory as) the second quantity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed herein could be termed a second element, component, region, layer or section, without departing from the spirit and scope of the inventive concept.

The terminology used herein is for the purpose of describing particular embodiments only and is not intended to be limiting of the inventive concept. As used herein, the terms “substantially,” “about,” and similar terms are used as terms of approximation and not as terms of degree, and are intended to account for the inherent deviations in measured or calculated values that would be recognized by those of ordinary skill in the art.

As used herein, the singular forms “a” and “an” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Further, the use of “may” when describing embodiments of the inventive concept refers to “one or more embodiments of the present disclosure”. Also, the term “exemplary” is intended to refer to an example or illustration. As used herein, the terms “use,” “using,” and “used” may be considered synonymous with the terms “utilize,” “utilizing,” and “utilized,” respectively.

It will be understood that when an element or layer is referred to as being “on”, “connected to”, “coupled to”, or “adjacent to” another element or layer, it may be directly on, connected to, coupled to, or adjacent to the other element or layer, or one or more intervening elements or layers may be present. In contrast, when an element or layer is referred to as being “directly on”, “directly connected to”, “directly coupled to”, or “immediately adjacent to” another element or layer, there are no intervening elements or layers present.

Any numerical range recited herein is intended to include all sub-ranges of the same numerical precision subsumed within the recited range. For example, a range of “1.0 to 10.0” or “between 1.0 and 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Similarly, a range described as “within 35% of 10” is intended to include all subranges between (and including) the recited minimum value of 6.5 (i.e., (1−35/100) times 10) and the recited maximum value of 13.5 (i.e., (1+35/100) times 10), that is, having a minimum value equal to or greater than 6.5 and a maximum value equal to or less than 13.5, such as, for example, 7.4 to 10.6. Any maximum numerical limitation recited herein is intended to include all lower numerical limitations subsumed therein and any minimum numerical limitation recited in this specification is intended to include all higher numerical limitations subsumed therein.

Although exemplary embodiments of a system and method for storing a power delay profile in compressed form have been specifically described and illustrated herein, many modifications and variations will be apparent to those skilled in the art. Accordingly, it is to be understood that a system and method for storing a power delay profile in compressed form constructed according to principles of this disclosure may be embodied other than as specifically described herein. The invention is also defined in the following claims, and equivalents thereof.

What is claimed is:

1. A method, comprising:
identifying, in a power delay profile comprising a first group of taps, a first arrival tap corresponding to a first arrival path;
identifying a first subset of taps, the first subset being a subset of the first group and including the first arrival tap;
identifying a second subset of taps, the second subset being a subset of the first group and being disjoint from the first subset; and
storing, in a memory, the union of the first subset and a proper subset of the second subset.

2. The method of claim 1, wherein the first group of taps includes all of the taps of the power delay profile.

3. The method of claim 1, wherein the power delay profile further comprises a second group of taps, the second group and the first group being disjoint.

4. The method of claim 3, further comprising:
identifying a principal tap within the second group;
identifying a third subset of taps, the third subset being a subset of the second group, and including the principal tap;
identifying a fourth subset of taps, the fourth subset being a subset of the second group and being disjoint from the third subset; and
storing, in the memory, the union of the third subset and a proper subset of the fourth subset.

5. The method of claim 1, wherein the first subset includes a first contiguous plurality of taps including a tap immediately adjacent to and delayed with respect to the first arrival tap and a second contiguous plurality of taps including a tap immediately adjacent to and advanced with respect to the first arrival tap.

6. The method of claim 5, wherein the first contiguous plurality of taps includes more taps than the second contiguous plurality of taps.

7. The method of claim 1, further comprising identifying the proper subset of the second subset, the identifying comprising excluding a regularly spaced subset from the second subset.

8. The method of claim 1, further comprising reconstituting, from taps stored in the memory, a decompresssed power delay profile.

9. The method of claim 8, wherein the reconstituting of the decompresssed power delay profile comprises using linear interpolation.

10. The method of claim 8, wherein the reconstituting of the decompresssed power delay profile comprises using simple extension.

11. A User Equipment, comprising:
a processing circuit; and
memory connected to the processing circuit,
the memory storing instructions that, when executed by the processing circuit, cause the User Equipment to perform a method, the method comprising:
identifying, in a power delay profile comprising a first group of taps, a first arrival tap corresponding to a first arrival path;
identifying a first subset of taps, the first subset being a subset of the first group, and including the first arrival tap;
identifying a second subset of taps, the second subset being a subset of the first group and being disjoint from the first subset; and
storing, in a memory, the union of the first subset and a proper subset of the second subset.

12. The User Equipment of claim 11, wherein the first group of taps includes all of the taps of the power delay profile.

13. The User Equipment of claim 11, wherein the power delay profile further comprises a second group of taps, the second group and the first group being disjoint.

14. The User Equipment of claim 13, wherein the method further comprises:
identifying a principal tap within the second group;
identifying a third subset of taps, the third subset being a subset of the second group, and including the principal tap;
identifying a fourth subset of taps, the fourth subset being a subset of the second group and being disjoint from the third subset; and
storing, in the memory, the union of the third subset and a proper subset of the fourth subset.

15. The User Equipment of claim 11, wherein the first subset includes a first contiguous plurality of taps including a tap immediately adjacent to and delayed with respect to the first arrival tap and a second contiguous plurality of taps including a tap immediately adjacent to and advanced with respect to the first arrival tap.

16. The User Equipment of claim 15, wherein the first contiguous plurality of taps includes more taps than the second contiguous plurality of taps.

17. The User Equipment of claim 11, wherein the method further comprises identifying the proper subset of the second subset, the identifying comprising excluding a regularly spaced subset from the second subset.

18. The User Equipment of claim 11, wherein the method further comprises reconstituting, from taps stored in the memory, a decompresssed power delay profile.

19. The User Equipment of claim 18, wherein the reconstituting of the decompresssed power delay profile comprises using linear interpolation.

20. A User Equipment, comprising:
means for processing; and
memory connected to the means for processing,
the memory storing instructions that, when executed by the means for processing, cause the User Equipment to perform a method, the method comprising:
identifying, in a power delay profile comprising a first group of taps, a first arrival tap corresponding to a first arrival path;
identifying a first subset of taps, the first subset being a subset of the first group, and including the first arrival tap;
identifying a second subset of taps, the second subset being a subset of the first group and being disjoint from the first subset; and
storing, in a memory, the union of the first subset and a proper subset of the second subset.
